(19) United States
(12) Patent Application Publication
(10) Pub. No.: US 2004/0032291 A1
(43) Pub. Date: Feb. 19, 2004

(54) TFT level shifter of low operational voltage

(76) Inventor: Jung-Chuh Tseng, Pingtung (TW)

Correspondence Address: MADSON & METCALF, GATEWAY TOWER WEST, SUITE 900, 15 WEST SOUTH TEMPLE, SALT LAKE CITY, UT, 84101

(21) Appl. No.: 10/456,884

(22) Filed: Jun. 6, 2003

(30) Foreign Application Priority Data
Aug. 16, 2002 (TW) 91118601

(51) Int. Cl. H03L 5/00

(52) U.S. Cl. 327/333

(57) ABSTRACT

A voltage-level shifing device of a low operational voltage receives a first and a second clock signals in complement to each other, and includes a first pre-shifter generating a third clock signal in response to the first clock signal, wherein a high level of the first clock signal is lower than a high level of the third clock signal; a second pre-shifter generating a fourht clock signal in response to the second clock signal, a high level of the second clock signal being lower than a high level of the fourth clock signal; and a downstream level shifter electrically connected to the first and second pre-shifters, receiving the second and fourth clock signals, and outputting a signal having a high level greater than a high level of either of the second and fourth clock signals according to a variation of the second and fourth clock signals.

### FIELD OF THE INVENTION

The present invention relates to a level shifter, and more particular to a TFT level shifter of a low operational voltage.

### BACKGROUND OF THE INVENTION

With the trend of e-life, computers are more and more popular and important in various fields. The requirement on the quality of the computers is also getting critical. For example, modern computers have to be quick, reliable, beautiful, and environment-friendly, and so do the displaying apparatus of the computers. Conventional CRT (cathode ray tube) monitors are bulky and radioactive, and thus gradually substituted by liquid crystal displays (LCDs), and more particularly the thin film transistor liquid crystal displays (TFTLCDs).

In general, a drive circuit is required for scanning the TFT array when the TFTLCD is in operation. The display data is then stored into each cell of the TFT array. In the drive circuit, a level shifter is used for converting a clock signal of a low voltage level into that of a high voltage level. The clock signal of the high voltage level allows the TFT units in the TFT array to be actuated rapidly and completely, and the voltage signals signifying the display data to be transmitted to the display cells rapidly and completely.

FIG. 1 is a schematic circuit diagram showing a level shifer of prior art. The level shifter is implemented by a thin film transistor. Due to the advance of manufacturing processes, the level shifter can be formed on the display panel along with the formation of the TFT array. The source electrodes of the P-type TFTs 115 and 120 are electrically connected to the voltage source (Vdd) that is 12 volts. The gate electrode of the P-type TFT 115 is electrically connected to the P-type TFT 120 and the drain electrode of the P-type TFT 115. Meanwhile, a current mirror structure 145 is formed between the P-type TFT 115 and the P-type TFT 120.

The drain electrodes of the P-type TFTs 115 and 120 are electrically connected to the drain electrodes of the N-type TFTs 105 and 110, respectively. The source electrodes of the N-type TFTs 105 and 110 are grounded. The gate electrodes of the N-type TFTs 105 and 110 are electrically connected to the clock sources 125 and 130, respectively, wherein the two clock sources 125 and 130 are complement to each other. Accordingly, the N-type TFTs 105 and 110 constitute a differential pair circuit 150 with the N-type TFT 110 serving as the output end of the circuit.

When the clock source 125 is at a high level, i.e. logic “1”, the other clock source 130 is at a low level, i.e. logic “0”. Therefore, in the differential pair circuit 150, the N-type TFT 105 is opened, and the N-type TFT 110 is closed. Meanwhile, the voltage at the output end approximates to the voltage source. On the contrary, when the clock source 125 is at a low level, i.e. logic “0”, the other clock source 130 is at a high level, i.e. logic “1”. Therefore, in the differential pair circuit 150, the N-type TFT 105 is closed, and the N-type TFT 110 is opened. Meanwhile, the voltage at the output end approximates to the ground voltage.

When the levels of the clock sources 125 and 130 are alternately changed, the level of the output end 140 is also alternately high and low. A clock signal between the voltage source (12V) and the ground voltage (0V) is thus obtained at the output end 140. In other words, the voltage level shifter converts a clock signal of a relatively low voltage level into a clock signal of a relatively high voltage level.

As shown in the circuit of FIG. 1, in order to repetitively switch the N-type TFTs 105 and 110 of the differential pair circuit 150, the voltage levels of the clock sources 125 and 130 have to be greater than the threshold voltages of the N-type TFTs 105 and 110. The N-type TFTs 105 and 110 are then effectively opened/closed in response to the input of the clock sources 125 and 130.

Due to the limitation on the TFT technology, the threshold voltage of the TFT is generally relatively high. As such, the clock sources 125 and 130 have to operate in a relatively high voltage level. In general, the threshold voltage of an N-type TFT is around 3 volts. In other words, the clock sources 125 and 130 typically operate at a level no less than 3 volts in order to properly open the N-type TFTs 105 and 110. This results in much power consumption of the application specific integrated circuit (ASIC) where the clock sources are generated.

Therefore, an object of the present invention is to provide a TFT level shifter of a low operational voltage to solve the problem encounted in the prior art as mentioned above.

### SUMMARY OF THE INVENTION

A first aspect of the present invention relates to a voltage-level shifing device. The voltage-level shifting device receives a first and a second clock signals in complement to each other, and comprises a first pre-shifter generating a third clock signal in response to the first clock signal, wherein a high level of the first clock signal is lower than a high level of the third clock signal; a second pre-shifter generating a fourht clock signal in response to the second clock signal, a high level of the second clock signal being lower than a high level of the fourth clock signal; and a downstream level shifter electrically connected to the first and second pre-shifters, receiving the second and fourth clock signals, and outputting a signal having a high level greater than a high level of either of the second and fourth clock signals according to a variation of the second and fourth clock signals.

Preferably, the first pre-shifter includes a voltage divider coupled in between a voltage source and the first clock signal for generating the third clock signal. The voltage divider preferably includes a plurality of resistor elements interconnected in series. More preferably, the resistor elements includes a P-type thin film transistor having a gate electrode thereof grounded, and/or a P-type thin film transistor having interconnected gate and source electrodes.

Preferably, the second pre-shifter also includes a voltage divider coupled in between a voltage source and the second clock signal for generating the fourth clock signal. The voltage divider includes a plurality of resistor elements interconnected in series.

Preferably, the downstream level shifter includes a current mirror structure electrically connected to a voltage source, and including two P-type thin film transistors; and a differential pair circuit electrically connected to the current mirror structure and the first and second pre-sifters, and including two N-type thin film transistors.

### DESCRIPTION OF THE DRAWINGS

The present invention may best be understood through the following description with reference to the accompanying drawings, in which:

FIG. 1 is a schematic circuit diagram showing a TFT level shifer prior art;

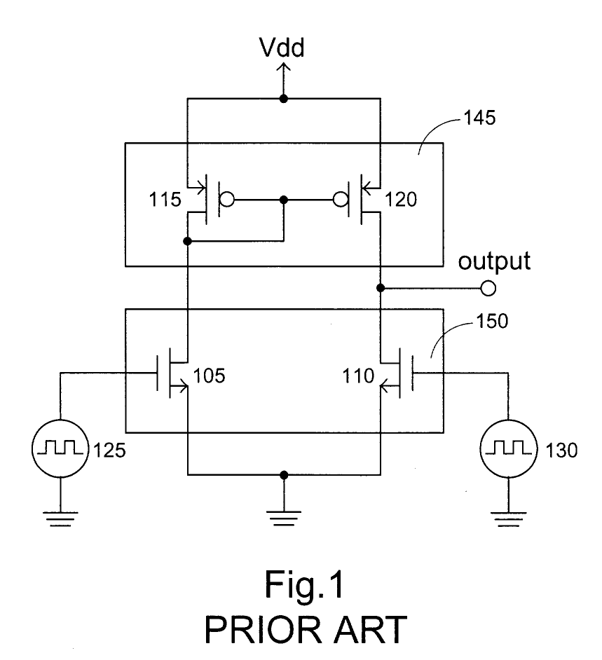

FIG. 2 is a schematic circuit diagram showing a TFT level shifer according to the present invention; and

FIG. 3 is a schematic waveform diagram associated with the TFT level shifer according to the present invention.

### DETAILED DESCRIPTION OF THE PREFERRED EMBODIMENT

The present invention will now be described more specifically with reference to the following embodiments. It is to be noted at the following descriptions of preferred embodiments of this invention are presented herein for purpose of illustration and description only; it is not intended to be exhaustive or to be limited to the precise form disclosed.

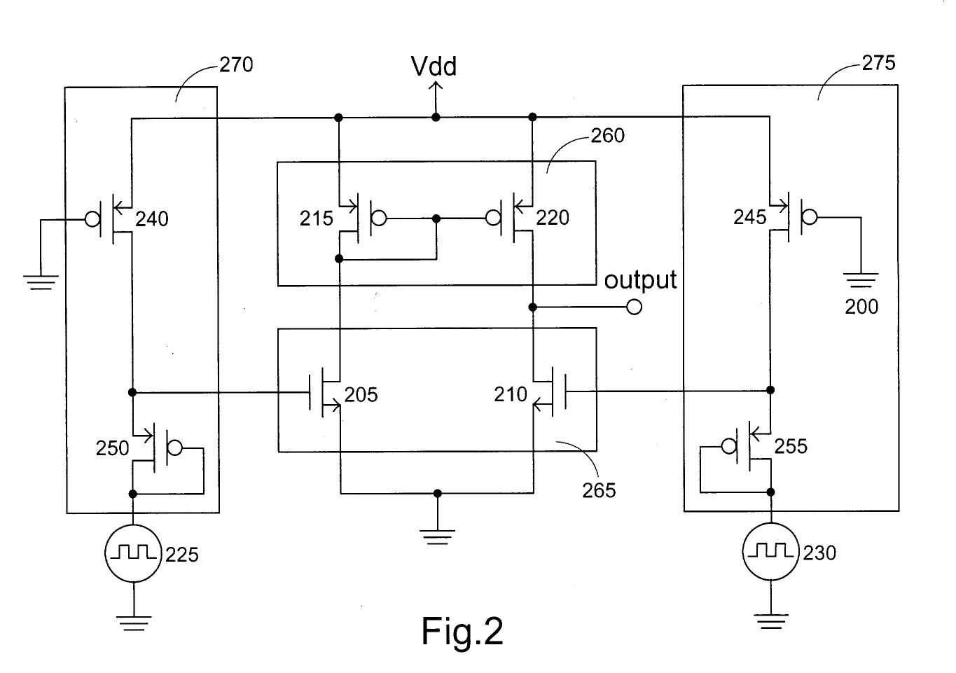

An embodiment of a TFT level shifter of a low operational voltage according to the present invention is described with reference to FIG. 2. The source electrodes of the P-type TFTs 215 and 220 are coupled to a high voltage source (Vdd). The gate electrode of the P-type TFT 215 is electrically connected to the P-type TFT 220 and the drain electrode of the P-type TFT 215. Meanwhile, a current mirror structure 260 is formed between the P-type TFT 215 and the P-type TFT 220.

The drain electrodes of the P-type TFTs 215 and 220 are electrically connected to the drain electrodes of the N-type TFTs 205 and 210, respectively. The source electrodes of the N-type TFTs 205 and 210 are grounded. Accordingly, the N-type TFTs 205 and 210 constitute a differential pair circuit 265.

In order to solve the problem encountered in the prior art, two pre-shifters 270 and 275 are coupled to the gate electrodes of the N-type TFTs 205 and 210, respectively. In the pre-shifter 270 consisting of P-type TFTs 240 and 250, the drain electrode of the P-type TFT 240 is electrically connected to a high voltage source (Vdd), and the gate electrode thereof is grounded. The drain electrodes of the P-type TFTs 240 and 250 are interconnected to each other and electrically connected to the gate electrode of the N-type TFT 205. Further, the gate and drain electrodes of the P-type TFT 250 are interconnected to each other. On the other hand, in the pre-shifter 275 consisting of P-type TFTs 245 and 255, the drain electrode of the P-type TFT 245 is electrically connected to a high voltage source (Vdd), and the gate electrode thereof is grounded. The drain electrodes of the P-type TFTs 245 and 255 are interconnected to each other and electrically connected to the gate electrode of the N-type TFT 210. Further, the gate and drain electrodes of the P-type TFT 255 are interconnected to each other.

The P-type TFTs 240 and 245 of the two pre-shifters 270 and 275 are both coupled to the ground voltage, and thus considered to be in an open status. They have equivalent resistance R1. Similarly, the P-type TFTs 250 and 255 have respective gate and drain electrodes thereof connected to each other, and thus considered as a diode-connection load. They have equivalent resistance R2 varying with the input voltage.

In operation, the drain electrode of the P-type TFT 250 serves as the input end of the pre-shifter 270, and a clock source 225 of a first low operational voltage level is inputted therefrom. The drain electrode of the P-type TFT 255 serves as the input end of the pre-shifter 275, and a clock source 230 of a second low operational voltage level is inputted therefrom. It is to be noted that the clock sources 225 and 230 are complement to each other.

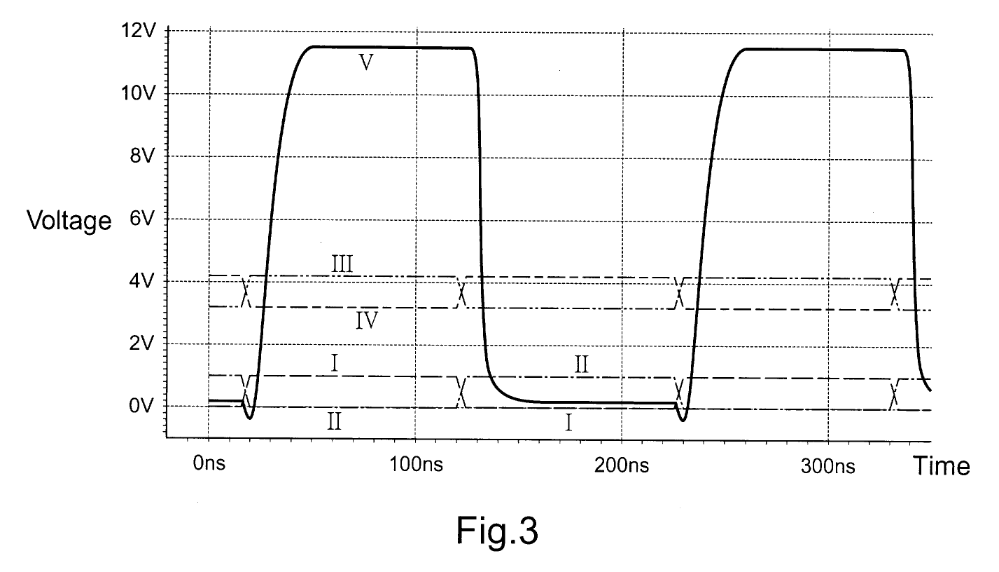

The associated waveforms of the TFT level shifer according to the present invention are illustrated hereinafter with reference to FIG. 3. At 100 ns, the clock source 225 of the first low operational voltage level, as indicated by Waveform I, is at a specific high voltage, i.e. logic “1”, and the clock source 230 of the second low operational voltage level, as indicated by Waveform II, is at a specific low voltage, i.e. logic “0”. In an embodiment, the specific high voltage is 1 volt and the specific low voltage is 0 volt. The P-type TFTs 240 and 250 of the first pre-shifter 270 properly divide the voltage by a formula of (1+(12−1)*R2/(R1+R2)). Then, a specific actuating voltage of the gate electrode of the N-type TFT 205 in the differential pair circuit 265, as indicated by the waveform III, is obtained. In this embodiment, the specific actuating voltage is 4.2 volts that is much higher than the threshold voltage of the N-type TFT 205. Therefore, the N-type TFT 205 is completely actuated. On the other hand, the P-type TFTs 245 and 255 of the first pre-shifter 275 properly divide the voltage by a formula of (1+(12−0)*R2/(R1+R2)). Then, a specific shutting-off voltage of the gate electrode of the N-type TFT 210 in the differential pair circuit 265, as indicated by the waveform IV, is obtained. In this embodiment, the specific actuating voltage is 3.2 volts that is slightly higher than the threshold voltage of the N-type TFT 210. Therefore, the N-type TFT 205 is slightly actuated, and the voltage at the output end, about 11.6 volts, approximates to the voltage source.

On the other hand, at 200 ns, the clock source 225 of the first low operational voltage level is at a specific low voltage, i.e. logic “0”, and the clock source 230 of the second low operational voltage level is at a specific high voltage, i.e. logic “1”. After the P-type TFTs 240 and 250 of the first pre-shifter 270 properly divide the voltage, a specific shutting-off voltage of the gate electrode of the N-type TFT 205 in the differential pair circuit 265, which is slightly higher than the threshold voltage of the N-type TFT 205, is obtained. Therefore, the N-type TFT 205 is slightly actuated. On the other hand, after the P-type TFTs 245 and 255 of the first pre-shifter 275 properly divide the voltage, a specific actuating voltage of the gate electrode of the N-type TFT 210 in the differential pair circuit 265, which is much higher than the threshold voltage of the N-type TFT 210, is obtained. Therefore, the N-type TFT 205 is completely actuated, and the voltage at the output end, about 0 volt, approximates to the ground voltage.

Further, in order to properly determining the specific actuating and shutting-off voltage values, the channel width between the P-type TFTs 240 and 250 and that between the P-type TFTs 245 and 255 are adjusted to properly dividing voltage.

When the voltages of the clock sources 225 and 230 are repetitively switched between 0 volt and 1 volt, the voltages at the output ends are also repetitively switched between 0 volt and 12 volts.

The level shifter of the present invention can be integrated to the display panel of a TFTLCD. A clock source of 1 volt substitutes for the prior art one of 3 volts or more so as to significantly reduce the input voltage values. Due to the reduction of the operation voltage, the power consumption of the ASCI providing the clock sources decreases.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A voltage-level shifing device, receiving a first and a second clock signals in complement to each other, and comprising:
a first pre-shifter generating a third clock signal in response to said first clock signal, a high level of said first clock signal being lower than a high level of said third clock signal;
a second pre-shifter generating a fourht clock signal in response to said second clock signal, a high level of said second clock signal being lower than a high level of said fourth clock signal; and
a downstream level shifter electrically connected to said first and second pre-shifters, receiving said second and fourth clock signals, and outputting a signal having a high level greater than a high level of either of said second and fourth clock signals according to a variation of said second and fourth clock signals.

2. The voltage-level shifing device according to claim 1 wherein said first pre-shifter includes a voltage divider coupled in between a voltage source and said first clock signal for generating said third clock signal.

3. The voltage-level shifing device according to claim 2 wherein said voltage divider includes a plurality of resistor elements interconnected in series.

4. The voltage-level shifing device according to claim 3 wherein said resistor elements includes a P-type thin film transistor having a gate electrode thereof grounded.

5. The voltage-level shifing device according to claim 3 wherein said resistor elements includes a P-type thin film transistor having interconnected gate and source electrodes.

6. The voltage-level shifing device according to claim 1 wherein said second pre-shifter includes a voltage divider coupled in between a voltage source and said second clock signal for generating said fourth clock signal.

7. The voltage-level shifing device according to claim 6 wherein said voltage divider includes a plurality of resistor elements interconnected in series.

8. The voltage-level shifing device according to claim 7 wherein said resistor elements includes a P-type thin film transistor having a gate electrode thereof grounded.

9. The voltage-level shifing device according to claim 7 wherein said resistor elements includes a P-type thin film transistor having interconnected gate and source electrodes.

10. The voltage-level shifting device according to claim 1 wherein said downstream level shifter includes:
a current mirror structure electrically connected to a voltage source, and including two P-type thin film transistors; and
a differential pair circuit electrically connected to said current mirror structure and said first and second pre-shifters, and including two N-type thin film transistors.
